(19) United States
(12) Patent Application Publication
(10) Pub. No.: US 2007/0284571 A1
(43) Pub. Date: Dec. 13, 2007

(54) ORGANIC THIN-FILM TRANSISTOR, METHOD OF MANUFACTURING SAME AND EQUIPMENT FOR MANUFACTURING SAME

(76) Inventors: Akira Doi, Hitachinaka (JP); Tomohiro Inoue, Tsukuba (JP); Masahiko Ando, Hitachinaka (JP); Masakazu Kishi, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/748,567

(22) Filed: May 15, 2007

(30) Foreign Application Priority Data
May 17, 2006 (JP) 2006-137220

(51) Int. Cl. H01L 29/08; H01L 35/24; H01L 51/00

(52) U.S. Cl. 257/40

(57) ABSTRACT

An organic thin-film transistor (TFT) with a large carrier mobility includes a drain electrode, a source electrode, which are made of different materials, and a semiconductor layer formed on upper surface of a substrate. Equipment for manufacturing the organic TFT comprises a substrate mounting unit, a painting unit, a light irradiating unit, a sealed container for housing the above units, and a gas supplying unit of an antioxidant gas to the sealed container. The organic TFT to be manufactured is placed on the substrate mounting unit and a semiconductor layer is formed by using the painting unit. The painted semiconductor layer is dried with a light by using the light irradiating unit. When the light with substantially uniform wavelength is irradiated to the drain and the source electrodes, a temperature gradient is caused in the semiconductor layer. Accordingly, an organic TFT with a large carrier mobility can be manufactured.

The present application claims priority from Japanese application serial no. 2006-137220 filed on May 17, 2006, the content of which is hereby incorporated by reference into this application.

### BACKGROUND OF THE INVENTION

1. Field of the Invention

The present invention relates to an organic thin-film transistor, as well as a method and an equipment for manufacturing the organic thin-film transistor.

2. Description of the Related Art

In thin display units using liquid crystal or organic electroluminescent (EL) devices, thin-film transistors (TFTs) made of an inorganic semiconductor such as amorphous silicon or polycrystalline silicon are employed as a pixel driving element. Usually, a plasma chemical vapor deposition (CVD) apparatus or a sputtering apparatus is used to form semiconductor layers and electrodes when TFTs are manufactured. However, it has been required that TFTs are fabricated at a low cost and/or have flexibility. Then, methods of manufacturing TFTs using a painting technology such as ink jet, screen printing or the like for applying an organic semiconductor are being considered.

An example of this type of TFT manufacturing method is described in JP-A No. 2001-345267. In the manufacturing method of an inorganic TFT described in this document, the semiconductor layer is locally irradiated with a laser beam by using a mask. This local irradiation causes a temperature distribution in the semiconductor layer, adjusting diameters of crystal grains and increasing the carrier mobility of the inorganic TFT.

In the TFT manufacturing method described in the document, after an organic insulating film is coated, the insulating film is heated by a clean oven or a hot plate. In this method, it is preferable to perform the heating immediately after the coating. However, it is hard to move between apparatuses, since the organic insulating layer in liquid form is easy to flow immediately after the coating. On the other hand, the use of masks during the heating process causes another problem; a mask is required for each pattern, so when different patterns are created, different masks are needed and the cost of masks increases.

### SUMMARY OF THE INVENTION

Under these circumstances, it is an object of the present invention to provide an organic TFT controlled on a crystal growth of a semiconductor material that is formed by using a printing method. It is a further object of the present invention to provide a method of manufacturing an organic TFT and to provide an equipment for manufacturing the same in order to improve efficiency of the manufacturing and/or to increase reliability of the manufacturing.

(1) According to an embodiment of the present invention, an organic thin-film transistor comprises an insulating layer formed on a substrate, a source electrode formed on the insulating layer, a drain electrode formed on the insulating layer; and a semiconductor layer formed on the insulating layer and between the source electrode and the drain electrode; wherein the source electrode and the drain electrode are made of different materials and show different temperature rises when a light with predetermined wavelength is irradiated to the electrodes.

In the above invention (1), the following modifications and changes can be made.

(i) The source electrode and the drain electrode are formed on upper surface of the substrate; and are made of any one of gold, silver, copper, chromium, aluminum, and nickel.

(ii) The source electrode is made of copper, and the drain electrode is made of silver; and the wavelength of the light to be irradiated is approximately 0.4 μm.

(2) According to another embodiment of the present invention, an equipment for manufacturing an organic thin-film transistor comprises a painting unit of a semiconductor material to a substrate having an organic thin film, a substrate mounting unit on which the substrate is mounted, a light irradiating unit for drying the semiconductor material painted on the substrate, a sealed container for housing the above units, and a gas supplying unit to the sealed container; wherein the light irradiating unit irradiates a light with substantially uniform wavelength to the substrate having a source electrode, a drain electrode and the semiconductor material; and a temperature gradient is caused in the semiconductor material by the irradiated light.

In the above invention (2), the following modifications and changes can be made.

(iii) The wavelength of the light is such that a ratio of the light reflected by the semiconductor material is higher than a ratio of the light absorbed by the semiconductor material.

(iv) The wavelength of the light is such that the reflectance of either of the source electrode and the drain electrode is higher than the absorptance thereof and such that the absorptance of the other is higher than the reflectance thereof.

(v) The light irradiating unit includes a lamp for generating light and a filter for making the wavelengths of the light generated by the lamp uniform; and the light with the uniform wavelength is irradiated to upper surface of the substrate to cause a temperature gradient in the semiconductor material.

(vi) The light irradiating unit has at least any one of a xenon lamp, a high-pressure mercury lamp, and a low-pressure mercury lamp; and the lamp is capable of irradiating a light with particular wavelengths.

(3) According to another embodiment of the present invention, a method of manufacturing an organic thin-film transistor comprises, the organic thin-film transistor includes a source electrode, a drain electrode, and a semiconductor layer on a substrate; wherein transferring the substrate into a sealed container, forming the semiconductor layer on the transferred substrate by using a painting unit, and irradiating a light with substantially uniform wavelength to the substrate on which the semiconductor layer is formed so as to cause a temperature gradient in the semiconductor layer.

In the above invention (3), the following modifications and changes can be made.

(vii) The drain electrode and the source electrode of the organic thin-film transistor are preferably made of different materials so that when the light with substantially uniform wavelength is irradiated to the different materials, reflectances thereof are different from each other.

(viii) The substrate of the organic thin-film transistor is a sheet in a film form and is capable of being transferred by using plural rollers disposed in the sealed container.

### ADVANTAGES OF THE INVENTION

According to the present invention, it is possible to provide an organic TFT controlled on a crystal growth of a semiconductor material that is formed by using a printing method. Further, it is possible to provide a method of manufacturing an organic TFT in which a drying process of a semiconductor layer is performed immediately after the semiconductor layer is formed, and generate a temperature gradient in the semiconductor layer so as to control a crystal growth of the semiconductor layer. Further, it is possible to provide an organic TFT manufacturing equipment which can control a crystal growth of a semiconductor layer formed on a substrate by a painting unit by means of a light irradiating unit during a drying process. As a result, the production efficiency of organic thin-film transistors is increased. Furthermore, since a complex and expensive apparatus (e.g., apparatus using a scanning laser beam) is no longer needed, the reliability and the cost of production are improved.

### BRIEF DESCRIPTION OF THE DRAWINGS

FIG. 1 is a schematic illustration showing a cross-sectional view of the front of equipment for manufacturing organic thin-film transistors in a preferred embodiment according to the present invention.

FIG. 2 is a schematic illustration showing a drying process in a manufacturing method of organic thin-film transistors using the equipment shown in FIG. 1 in a preferred embodiment according to the present invention.

FIG. 3 is a schematic illustration showing a top view of organic thin-film transistors in a preferred embodiment according to the present invention.

FIG. 4 is a graph showing the reflectance of a metal material as a function of the wavelength of light.

FIG. 5 is a schematic illustration showing a cross-sectional view of the front of equipment for manufacturing organic thin-film transistors in another preferred embodiment according to the present invention.

### DETAILED DESCRIPTION OF THE PREFERRED EMBODIMENTS

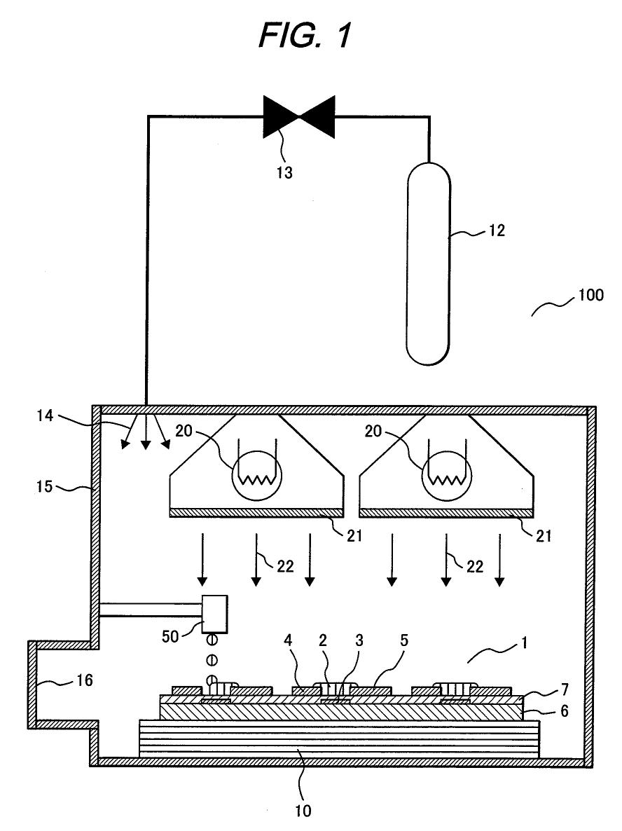

An equipment for manufacturing an organic thin-film transistor (TFT) will be described below with reference to the drawings. FIG. 1 is a schematic illustration showing a cross-sectional view of the front of TFT manufacturing equipment 100 in a preferred embodiment according to the present invention. TFT 1 comprises plural thin film layers stacked on a substrate 6. Gate electrodes 3 are disposed direct on the substrate 6 at some intervals. A gate insulating layer 7 is formed around each gate electrode 3. Drain electrodes 4, source electrodes 5, and semiconductor layers 2 are formed at different positions on these gate-related thin films (gate electrode 3 and gate insulating layer 7), as described in detail below.

The TFT 1 to be manufactured is supported by a stage 10 on which the TFT 1 is placed. The stage 10 has a temperature control means (not shown) for adjusting the temperature of the TFT 1. The stage 10 and the substrate 6 are disposed in a sealed container 15 for shielding the interior of the container 15 from the ambient air. The sealed container 15 is filled with a gas 14 such as a nitrogen gas or another gas that does not react with various types of semiconductor materials treated on a surface of the substrate 6. A gas inlet port is disposed to the container 15, to which a gas supplying unit 12 is connected through a flow rate control valve 13. The flow rate control valve 13 is used to adjust the amount of gas to be supplied to the sealed container 15.

A painting unit 50 used to form the semiconductor layers 2 on a surface of the substrate 6 is disposed above the substrate 6 and in the sealed container 15. A plurality of lamps 20 for drying the semiconductor layers 2 formed on the substrate 6 are mounted inside the sealed container 15 and in upper positions thereof. A filter 21 for controlling the wavelength of light emitted from each lamp 20 is disposed near the each lamp 20 and above the substrate 6. The filter 21 also serves so that the light 22 emitted from the lamp 20 is spread uniformly over the entire surface of the TFT 1. Furthermore, the substrate 6 is transferred from a transfer door 16 provided on a side of the sealed container 15 onto the stage 10 by means of a conveying means (not shown) before the semiconductor layers 2 are formed.

Next, a method of manufacturing the TFT 1 by using the TFT manufacturing equipment 100 structured as described above will be described. When manufacturing the TFT 1, the painting unit 50 ejects a liquid semiconductor material to form the semiconductor layers 2 on the substrate 6. At this time, the temperature of the stage 10 is adjusted in such a way that the semiconductor layers 2 formed on the substrate 6 keep from drying or that the progress of drying is delayed. After the semiconductor layers 2 are formed on the substrate 6, the temperature of the stage 10 is raised by using the temperature control means provided in the stage 10. Additionally, the lamp 20 is turned on to irradiate the light 22 with substantially uniform wavelength onto the TFT 1.

The materials of the drain electrode 4 and source electrode 5 as well as the wavelength of the light 22 to be irradiated to the drain electrode 4 and source electrode 5 are appropriately selected. The temperature of the stage 10 is adjusted to control an average temperature of each semiconductor layer, as described above. Further, the temperature gradient of each semiconductor layer due to the light irradiation is controlled so as to manufacture a TFT 1 with a large carrier mobility.

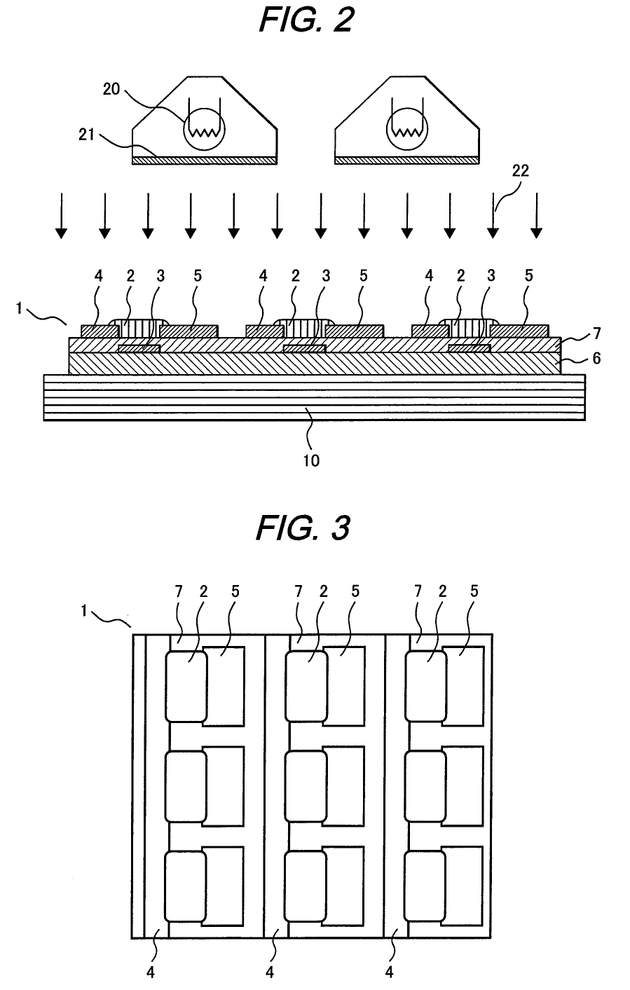

Next, a drying process in the manufacturing method and configuration of the organic thin-film transistors will be described more in detail with reference to FIGS. 2 and 3. FIG. 2 is a schematic illustration showing a drying process in a manufacturing method of organic thin-film transistors using the equipment shown in FIG. 1 in a preferred embodiment according to the present invention. As described above, the TFT 1 comprises the substrate 6; the gate electrodes 3 and the gate insulating layer 7, both of which are formed on the substrate 6; and the drain electrodes 4, the source electrodes 5 and the semiconductor layers 2, which are all formed on upper surface of the gate insulating layer 7.

FIG. 3 is a schematic illustration showing a top view of organic thin-film transistors shown in FIG. 2 in a preferred embodiment according to the present invention. As shown in FIG. 3, the semiconductor layers 2 formed on the substrate 6 are each approximately rectangular and are arranged on a grid. The source electrode 5 is formed adjacent to the right side of the semiconductor layer 2 in FIG. 3, the source electrode 5 being also approximately rectangular and slightly larger than the semiconductor layer 2. The left end side of the source electrode 5 vertically overlaps the semiconductor layer 2. The drain electrode 4 is disposed on the left end side of each semiconductor layer 2. The drain electrode 4 has a stripe shape and its right end side vertically overlaps a plurality of semiconductor layers 2.

The present invention features that a temperature gradient is caused on each semiconductor layer 2 in the drying process performed after the semiconductor layers 2 are formed. Accordingly, the light emitted from the lamp 20 disposed above the TFT 1 passes through the filter 21 so that the wavelength of the light is controlled by the filter 21. The light 22, the wavelength of which has been controlled by the filter 21, is then uniformly emitted on the entire surface of the TFT 1, as shown in FIG. 2.

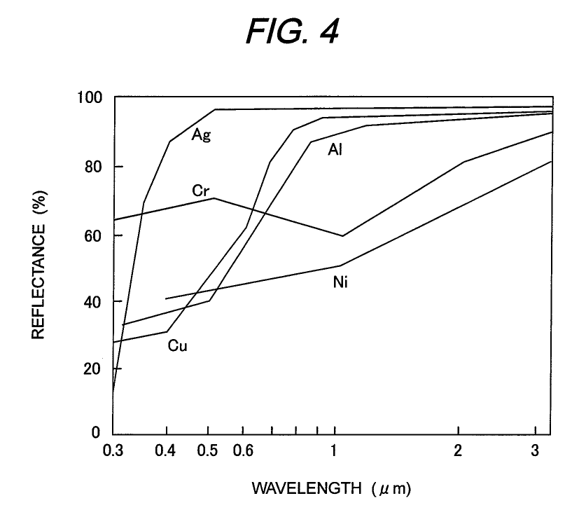

In order to cause a temperature gradient by use of the uniformed light 22, the drain electrode 4 and the source electrode 5 are made of different metal materials. In this embodiment, the wavelength of the light 22 passing through the filter 21 is set to be approximately 0.4 μm, and the drain electrode 4 and the source electrode 5 are made of silver and copper, respectively. FIG. 4 is a graph showing the reflectance of a metal material as a function of the wavelength of light. A reflectance of 100% indicates that the light is completely reflected, and a reflectance of 0% defines that the light is completely absorbed.

When the wavelength is 0.4 μm, about 70% of the light is absorbed by the copper material but only about 10% of the light is absorbed by the sliver material, as shown in FIG. 4. Accordingly, when the light with a wavelength of 0.4 μm is used as an irradiation, it is considered that absorption is significant in the case of the copper material, largely raising the temperature of the copper material. When the light with the same wavelength, that is, 0.4 μm, is emitted to the silver material, it is regarded that absorption is small and the temperature rise of the silver material is also small. Therefore, if the drain electrode 4 and the source electrode 5 are made of different materials and the wavelength and strength of the light 22 to be emitted are adjusted, as described above, the difference in temperatures at both ends of the semiconductor layer 2 can be controlled. Furthermore, if the temperature of the stage 10, on which the TFT 1 is placed, is also controlled, the average temperature of the semiconductor layer 2 can be also adjusted.

When the semiconductor layer 2 is made of pentacene, the temperature of the semiconductor layer 2 is set to be 150° C. or less so that the drying of the semiconductor layer 2 is delayed. In order to cause a temperature gradient in the semiconductor layer 2 by the method described above, the drain electrode 4 and the source electrode 5 are made of sliver and copper, respectively. The wavelength of the light 22 emitted through the filter 21 is set to be approximately 0.4 μm.

In the TFT 1 structured as described above, a temperature of the drain electrode 4 is lower than that of the source electrode 5 due to the light irradiation. In addition, the temperature of the stage 10 is controlled so that the temperature of the drain electrode 4 is within the range of 150 to 190° C. and the temperature of the source electrode 5 is about 200° C. Under these temperature conditions, the crystal growth of the semiconductor layer 2 is controlled, enabling a TFT 1 with a large carrier mobility to be manufactured. Furthermore, the temperature condition depends on the size of the TFT 1.

On the other hand, it is known that when ultraviolet radiation with a wavelength less than 0.4 μm is applied to pentacene, deterioration of the pentacene occurs. Then, the wavelength of the light 22 irradiated to the semiconductor layer 2 is preferably set to be 0.4 μm or more, and more preferably 0.4 μm or more and 0.5 μm or less. In this embodiment, the lamp 20 and the filter 21 for controlling the wavelength of the light emitted from the lamp 20 are provided to adjust the wavelength of the light 22 to be irradiated to the semiconductor layer 2. If a xenon lamp, a high-pressure mercury lamp, a low-pressure mercury lamp, or other lamp that emits light with a predetermined wavelength is used, it is less necessary to use the filter 21. In that case, however, it is necessary to select the materials of the source electrode 5 and the drain electrode 4 that adapt to the wavelength of the light from the lamp 20.

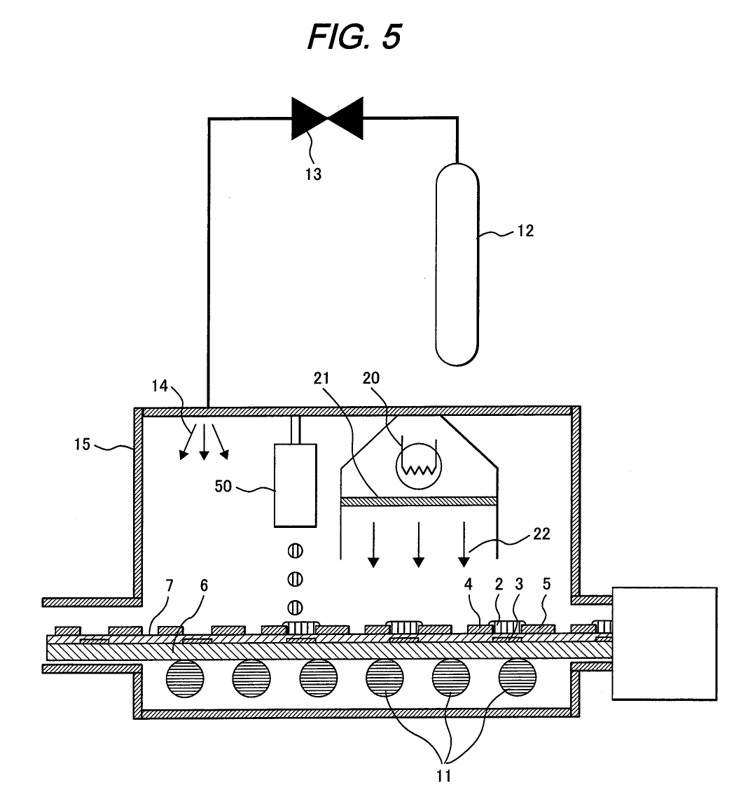

FIG. 5 is a schematic illustration showing a cross-sectional view of the front of equipment for manufacturing the organic TFT 1 in another preferred embodiment according to the present invention. This preferred embodiment features that plural conveying rollers 11 operable for transferring the substrate 6 are disposed below the substrate 6, instead of the fixed stage 10 as shown in FIG. 1. The conveying rollers 11, each of which has an axis length longer than a width of the substrate 6, support the bottom of the substrate 6. It is preferable that the conveying rollers 11 have a temperature control means (not shown) for adjusting the temperature of the TFT 1. The painting unit 50 of a semiconductor material and the lamp 20 are arranged in the container 15, above the substrate 6 and side-by-side in the moving direction of the substrate 6. Since the substrate 6 can be transferred in the container 15, the substrate 6 can be made of a film-like sheet.

Although not shown in the drawing (FIG. 5), the substrate 6 formed in a film form is wound on a supply reel on the left side of the container 15 and the substrate 6 that has been treated is wound on a take-up reel on the right side of the container 15. When a roller driving means (not shown) drives the rollers 11, the substrate 6 in a film form moves from the left side in FIG. 5 to the right side in FIG. 5. When the substrate 6 reaches a position below the painting unit 50, the painting unit 50 ejects paint of the semiconductor material, forming a semiconductor layers 2 on the substrate 6. After the semiconductor layers 2 are formed over a prescribed area, the rollers 11 are driven so as to move the formed semiconductor layers 2 to a position below the lamp 20. The semiconductor layers 2 are then dried in the same way as aforementioned embodiment shown in FIG. 1. After drying the semiconductor layers 2, the TFT 1 including the semiconductor layers 2 is sent to the take-up reel.

Organic thin-film transistors can be formed on a sheet in a film form in this preferred embodiment, and then they can be manufactured continuously. In aforementioned embodiment as shown in FIG. 1, the semiconductor material is painted on the substrate 6 by the painting unit 50, and then the entire surface of the substrate 6 is dried. On the other hand, in this embodiment, the drying process can be performed immediately and sequentially after the painting of the semiconductor material by driving the rollers 11. According to this embodiment, a TFT 1 in a film form can be manufactured, shortening a machine cycle for manufacturing the TFT 1.

According to the above embodiments, when materials of the drain electrode and the source electrode as well as the wavelength of the light irradiated to these electrodes are appropriately selected, the temperature gradient and the average temperature of the semiconductor layer can be adjustable, and control of the drying process enables TFTs with a large carrier mobility to be manufactured, thereby increasing a switching speed of the transistor. Moreover, since the temperature gradient can be caused just by irradiating light with uniform wavelength, a desired TFT can be easily manufactured.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. An organic thin-film transistor, comprising:
an insulating layer on a substrate, a source electrode formed on the insulating layer, a drain electrode formed on the insulating layer; and a semiconductor layer formed on the insulating layer and between the source electrode and the drain electrode; wherein:
the source electrode and the drain electrode are made of different materials and show different temperature rises when a light with predetermined wavelength is irradiated to the electrodes.

2. An organic thin-film transistor according to claim 1, wherein:
the source electrode and the drain electrode are formed on upper surface of the substrate; and are made of any one of gold, silver, copper, chromium, aluminum, and nickel.

3. An organic thin-film transistor according to claim 1, wherein:
the source electrode is made of copper, and the drain electrode is made of silver; and
the wavelength of the light to be irradiated is approximately 0.4 μm.

4. An equipment for manufacturing an organic thin-film transistor, comprising:
a painting unit of a semiconductor material to a substrate having an organic thin film, a substrate mounting unit on which the substrate is mounted, a light irradiating unit for drying the semiconductor material painted on the substrate, a sealed container for housing the above units, and a gas supplying unit to the sealed container; wherein:
the light irradiating unit irradiates a light with substantially uniform wavelength to the substrate having a source electrode, a drain electrode and the semiconductor material; and
a temperature gradient is caused in the semiconductor material by the irradiated light.

5. An equipment for manufacturing an organic thin-film transistor according to claim 4, wherein:
the wavelength of the light is such that a ratio of the light reflected by the semiconductor material is higher than a ratio of the light absorbed by the semiconductor material.

6. An equipment for manufacturing an organic thin-film transistor according to claim 4, wherein:
the wavelength of the light is such that the reflectance of either of the source electrode and the drain electrode is higher than the absorptance thereof and such that the absorptance of the other is higher than the reflectance thereof.

7. An equipment for manufacturing an organic thin-film transistor according to claim 4, wherein:
the light irradiating unit includes a lamp for generating light and a filter for making the wavelengths of the light generated by the lamp uniform; and
the light with the uniform wavelength is irradiated to upper surface of the substrate to cause a temperature gradient in the semiconductor material.

8. An equipment for manufacturing an organic thin-film transistor according to claim 4, wherein:
the light irradiating unit has at least any one of a xenon lamp, a high-pressure mercury lamp, and a low-pressure mercury lamp; and the lamp is capable of irradiating a light with particular wavelengths.

9. A method of manufacturing an organic thin-film transistor, comprising:
the organic thin-film transistor includes a source electrode, a drain electrode, and a semiconductor layer on a substrate, wherein:
transferring the substrate into a sealed container;
forming the semiconductor layer on the transferred substrate by using a painting unit; and
irradiating a light with substantially uniform wavelength to the substrate on which the semiconductor layer is formed so as to cause a temperature gradient in the semiconductor layer.

10. A method of manufacturing an organic thin-film transistor according to claim 9, wherein:
the drain electrode and the source electrode of the organic thin-film transistor are made of different materials so that when the light with substantially uniform wavelength is irradiated to the different materials, reflectances thereof are different from each other.

11. A method of manufacturing an organic thin-film transistor according to claim 9, wherein:
the substrate of the organic thin-film transistor is a sheet in a film form and is capable of being transferred by using plural rollers disposed in the sealed container.
